(19) United States
(12) Patent Application Publication
(10) Pub. No.: US 2008/0157291 A1
(43) Pub. Date: Jul. 3, 2008

(54) Packaging implementation while mitigating threshold voltage shifting

(75) Inventors: Lixia Li, Plano, TX (US); He Lin, Shanghai (CN)

Correspondence Address: TEXAS INSTRUMENTS INCORPORATED, P O BOX 655474, M/S 3999, DALLAS, TX, 75265, US

(73) Assignee: Texas Instruments Inc.

(21) Appl. No.: 11/657,206

(22) Filed: Jan. 24, 2007

Related U.S. Application Data
(60) Provisional application No. 60/877,298, filed on Dec. 27, 2006.

(51) Int. Cl. H01L 23/58; H01L 21/31

(52) U.S. Cl. 257/637; 438/763; 257/E21.24; 257/E23.01

(57) ABSTRACT

One or more passivation layers are added to the end of a semiconductor process flow to provide additional protection for devices (e.g., transistors) formed during the process. An additional layer is then formed and/or an anneal is performed to mitigate threshold voltage shifting that may be induced by the passivation layers. Mitigation of threshold voltage shifting increases the life expectancy of devices (e.g., transistors) formed during the process, which in turn mitigates yield loss by facilitating predictable or otherwise desirable behavior of the devices (e.g., transistors).

### REFERENCE TO RELATED APPLICATION

This application claims the benefit of U.S. Provisional Patent Application Ser. No. 60/877,298 which was filed Dec. 27, 2006, entitled PACKAGING IMPLEMENTATION WHILE MITIGATING THRESHOLD VOLTAGE SHIFTING.

### FIELD

The disclosure herein relates generally to semiconductor processing, and more particularly to implementing additional passivation layer(s) required by semiconductor die packaging while concurrently mitigating threshold voltage shifting that can arise there-from.

### BACKGROUND

Several trends presently exist in the semiconductor and electronics industry. Devices are continually being made smaller, faster and requiring less power. One reason for these trends is that more personal devices are being fabricated that are relatively small and portable, thereby relying on a battery as their primary supply. For example, cellular phones, personal computing devices, and personal sound systems are devices that are in great demand in the consumer market. In addition to being smaller and more portable, personal devices are also requiring increased memory and more computational power and speed. In light of these trends, there is an ever increasing demand in the industry for smaller and faster transistors used to provide the core functionality of the integrated circuits used in these devices.

Accordingly, in the semiconductor industry there is a continuing trend toward manufacturing integrated circuits (ICs) with higher densities. To achieve high densities, there has been and continues to be efforts toward scaling down dimensions (e.g., at submicron levels) on semiconductor wafers, that are generally produced from bulk silicon. In order to accomplish such high densities, smaller feature sizes, smaller separations between features, and more precise feature shapes are required in integrated circuits (ICs) fabricated on small rectangular portions of the wafer, commonly known as die. This may include the width and spacing of interconnecting lines, spacing and diameter of contact holes, as well as the surface geometry of various other features (e.g., corners and edges).

It can be appreciated that significant resources go into scaling down device dimensions and increasing packing densities. For example, significant man hours may be required to design such scaled down devices, equipment necessary to produce such devices may be expensive and/or processes related to producing such devices may have to be very tightly controlled and/or be operated under very specific conditions, etc. Accordingly, it can be appreciated that there can be significant costs associated with exercising quality control over semiconductor fabrication, including, among other things, costs associated with discarding defective units, and thus wasting raw materials and/or man hours, as well as other resources, for example. Additionally, since the units are more tightly packed on the wafer, more units are lost when some or all of a wafer is defective and thus has to be discarded. Accordingly, techniques that mitigate yield loss (e.g., a reduction in the number of acceptable or usable units), among other things, would be desirable.

### SUMMARY

The following presents a summary to provide a basic understanding of one or more aspects of the disclosure herein. This summary is not an extensive overview. It is intended neither to identify key or critical elements nor to delineate scope of the disclosure herein. Rather, its primary purpose is merely to present one or more aspects in a simplified form as a prelude to a more detailed description that is presented later.

One or more passivation layers are added to the end of a semiconductor process flow to provide additional protection for devices (e.g., transistors) during unit packaging. An additional layer is then formed and/or an anneal is performed to mitigate threshold voltage shifting that may be induced by the passivation layers. Mitigation of threshold voltage shifting increases the life expectancy of devices (e.g., transistors) formed during the process, which in turn mitigates yield loss by facilitating predictable or otherwise desirable behavior of the devices (e.g., transistors).

To the accomplishment of the foregoing and related ends, the following description and annexed drawings set forth certain illustrative aspects. Other aspects, advantages and/or features may, however, become apparent from the following detailed description when considered in conjunction with the annexed drawings.

### BRIEF DESCRIPTION OF THE DRAWINGS

FIG. 1 is a flow diagram illustrating an example methodology for implementing passivation layer(s) while concurrently mitigating threshold voltage shifting that can result there-from.

FIGS. 2-7 are cross-sectional views of an example semiconductor substrate whereon additional passivation layer(s) are formed, while threshold voltage shifting that can result there-from is concurrently mitigated.

FIG. 8 is a graph illustrating mitigation of threshold voltage shifting in a first technology.

FIG. 9 is a graph illustrating mitigation of threshold voltage shifting in a second technology.

### DETAILED DESCRIPTION

The description herein is made with reference to the drawings, wherein like reference numerals are generally utilized to refer to like elements throughout, and wherein the various structures are not necessarily drawn to scale. In the following description, for purposes of explanation, numerous specific details are set forth in order to facilitate understanding. It may be evident, however, to one skilled in the art, that one or more aspects described herein may be practiced with a lesser degree of these specific details. In other instances, known structures and devices are shown in block diagram form to facilitate understanding.

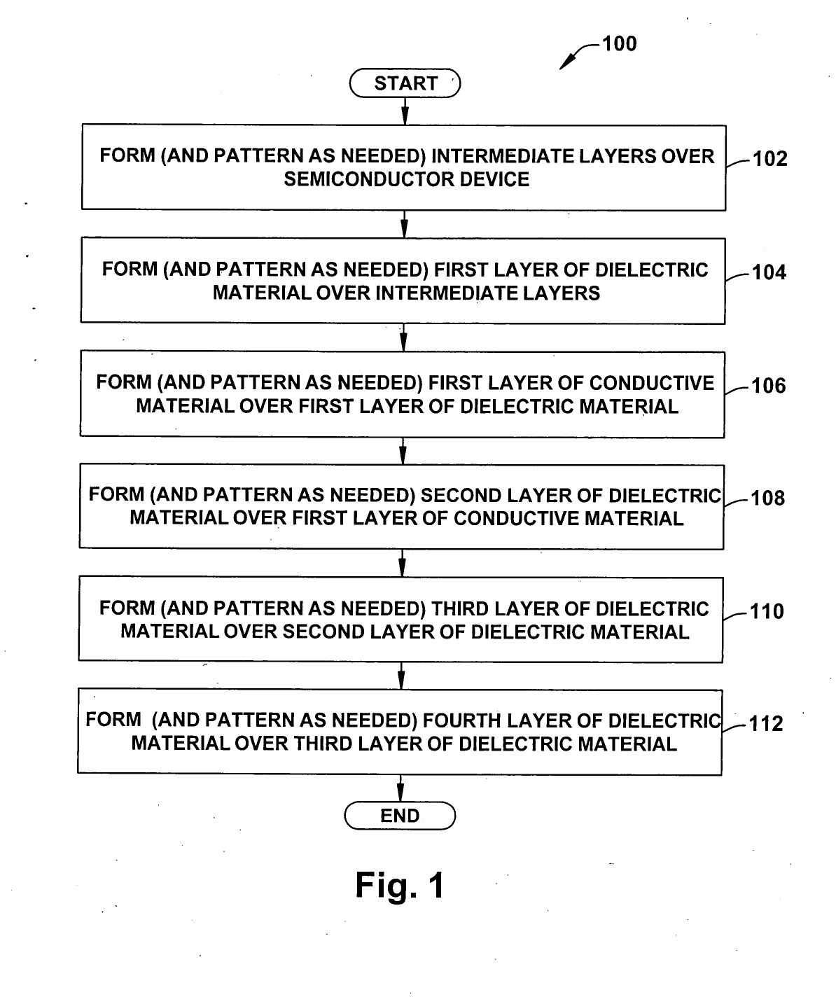

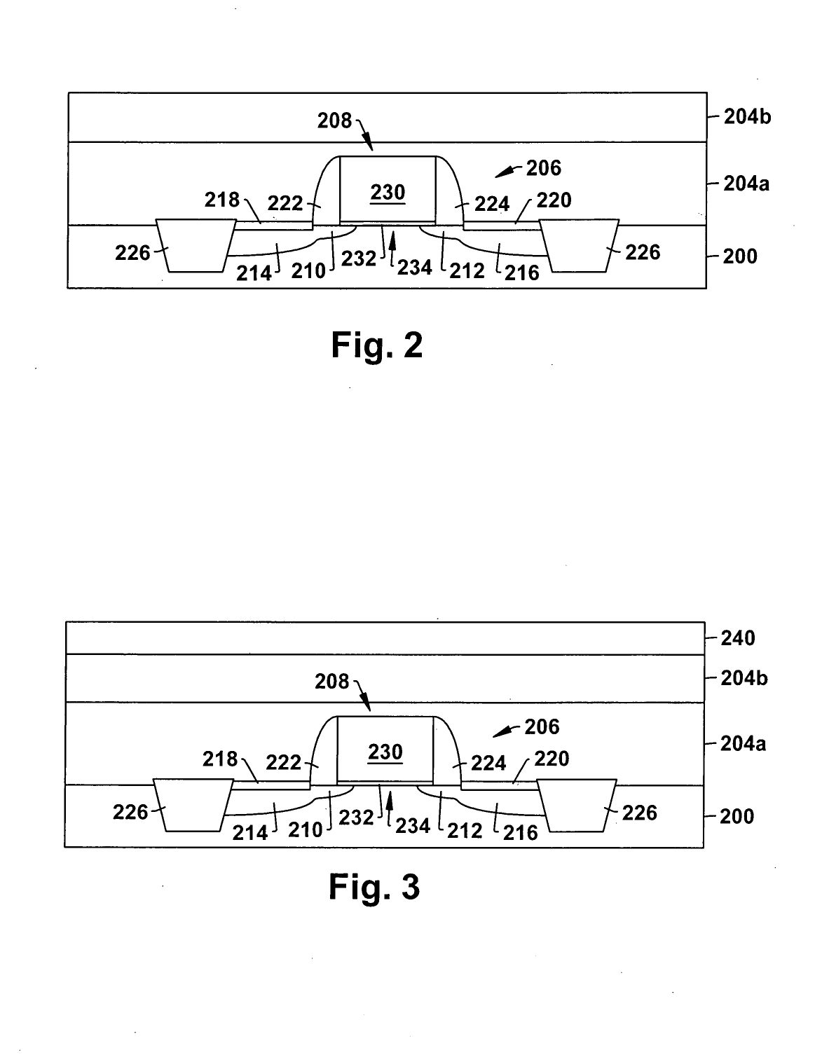

An example methodology 100 for implementing passivation layer(s) at the end of a semiconductor process flow, while concurrently mitigating threshold voltage shifting that can result there-from is illustrated in FIG. 1, and an example semiconductor substrate 200 whereon such a methodology is implemented is illustrated in cross-sectional view in FIGS. 2-7. While the method 100 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At 102, one or more intermediate or back end layers 204a, 204b of conductive, semi-conductive and/or non-conductive/dielectric layers of a semiconductor fabrication process are formed and patterned as needed (FIG. 2). There may, for example, be 2-7 of such layers, where contacts and/or electrically conductive vias, among other things, may be established therein. In the illustrated example, such layers 204a, 204b are formed over a transistor 206 formed in/on the semiconductor substrate 200. The transistor 206 generally comprises a gate structure or stack 208, a source extension region 210, a drain extension region 212, a source region 214, a drain region 216, a silicide 218 formed in/on the source region 214, a silicide 220 formed in/on the drain region 216 and first 222 and second 224 sidewall spacers adjacent the gate stack 208, among other things.

Dielectric materials 226 (e.g., shallow trench isolation (STI)) are formed in the substrate 200 to electrically isolate the transistor 206 from other/adjacent semiconductor devices, such as additional transistors, for example, (not shown) formed in/on the semiconductor substrate 200. The gate stack 208 comprises a gate electrode 230 and gate dielectric 232. The gate electrode 230 generally comprises a polysilicon (or other semiconductor) based material, and is formed to a thickness of between about 20 nm and about 200 nm, for example. The gate dielectric 232 generally comprises an oxide (or other dielectric) based material and/or a high-k material, for example, and is relatively thin, being formed to a thickness of between about 2 nm and about 20 nm, for example. A channel region 234 is defined in the substrate 200 between the source 210 and drain 212 extension regions and below the gate stack 208.

The transistor “operates”, at least in part, by conducting a current in the channel region 234 between the source 210 and drain 212 extension regions upon the application of certain voltages to the gate electrode 230 and source 214 and drain 216 regions. The transistor 206 may be used as a switch, for example, and may be regarded as being “on”, when a sufficient current is conduced therein, for example. It will be appreciated that the applied voltages are generally originated externally and are thus applied down through one or more vias and/or contacts (not shown) formed in layers 204a, 204b. The voltages are transferred to the source 214 and drain 216 regions by the electrically conductive silicide regions 218, 220 formed there-over, and are similarly applied to the gate electrode 230 by a silicide region (not shown) formed atop (at least some of) the gate electrode 230.

It will be appreciated that a voltage that causes a certain amount of current to flow within the transistor 206 may be regarded as the threshold voltage (Vt) of the transistor. Certain factors can cause this threshold voltage to “shift” or increase or decrease over time. For example, interface traps between the surface of substrate 200 and the gate dielectric 232 build up during the device usage due to weak surface bonding and cause the threshold voltage of the transistor 206 to shift. At some point, the threshold voltage may shift to such a degree that the transistor 206 may no longer be useful. For example, if the threshold voltage shifts up too much, the device may require too much power (which is a function of the required voltage) to operate (e.g., causing batteries to drain too quickly). It can thus be appreciated that the transistor 206 may be regarded as having a useful life, wherein the threshold voltage remains within an acceptable range.

It can be appreciated that, in addition to mitigating threshold voltage shifting, the longevity of the transistor 206 (and other semiconductor devices formed in/on the semiconductor substrate 200) may be enhanced by forming one or more passivation layers over layers 204a, 204b to provide protection from external contaminants, vibrations, shocks, etc. Accordingly, at 104 a first layer of dielectric passivation material 240 is formed over layers 204a, 204b (FIG. 3). This layer 240 is at times referred to as PO1, and may comprise silicon nitride and/or silicon oxide nitride and/or silicon oxide based materials, for example, formed to a thickness of between about 4 kilo Angstroms and about 24 kilo Angstroms, for example.

Layer 240 can also be patterned as needed, such as to facilitate the application of external biases, for example. It will be appreciated that this, as well as other patterning described herein, can be performed with lithographic techniques, where lithography refers to processes for transferring one or more patterns between various media. In lithography, a light sensitive resist coating is formed over one or more layers to which a pattern is to be transferred. The resist coating is then patterned by exposing it to one or more types of radiation or light which (selectively) passes through an intervening lithography mask containing the pattern. The light causes exposed or unexposed portions of the resist coating to become more or less soluble, depending on the type of resist used. A developer is then used to remove the more soluble areas leaving the patterned resist. The patterned resist can then serve as a mask for the underlying layer or layers which can be selectively treated (e.g., etched).

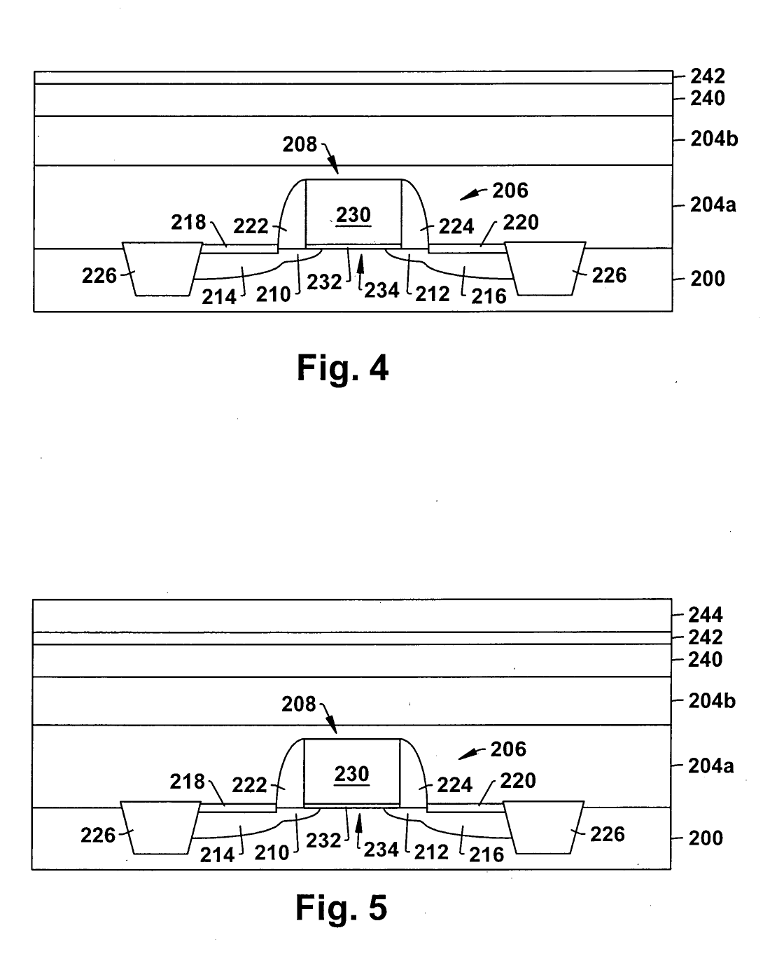

At 106, a first layer of conductive material 242 is formed over the first layer of dielectric passivation material 240 (FIG. 4). This layer 242 may comprise a top metal, for example, formed to a thickness of between about 4 kilo Angstroms and about 15 kilo Angstroms, for example. Layer 242 may also be patterned as needed to facilitate the application of external voltages, for example. At 108, a second layer of dielectric passivation material 244 is formed over the first layer of conductive material 242 (FIG. 5). This layer 244 is at times referred to as PO2, and may comprise silicon nitride and/or silicon oxide nitride and/or silicon oxide based materials, for example, formed to a thickness of between about 4 kilo Angstroms and about 24 kilo Angstroms, for example. Also, layer 244 can be patterned as needed to facilitate the application of external biases, for example.

It can be appreciated that given the nature of the materials applied, layer 244 and (to a lesser extent) layer 240 may be under compression, and that this compression may by transferred to the channel region 234 of transistor 206. Such compression can exacerbate threshold voltage shifting of the transistor 206, particularly if the transistor is a PMOS type transistor that has a negative bias applied to the gate—which is often the case with PMOS transistors. This threshold voltage shifting can be further exacerbated where the transistor is operated at a relatively high temperature, such as at 105 degrees Celsius or more, for example. This situation is at times referred to as negative bias temperature instability (NBTI), and is believed to be attributable, at least in part, to (weak) bonding issues between silicon and hydrogen atoms/molecules at the interface region between the substrate 200 and the gate dielectric 232. Similarly, it can also be appreciated that layers 244 and 240 can be treated (e.g., heated, cooled and/or applied in the presence of other materials) so that layer 244 and (to a lesser extent) layer 240 may be under tension. As with compression, this tension can lead to (NBTI) threshold voltage shifting.

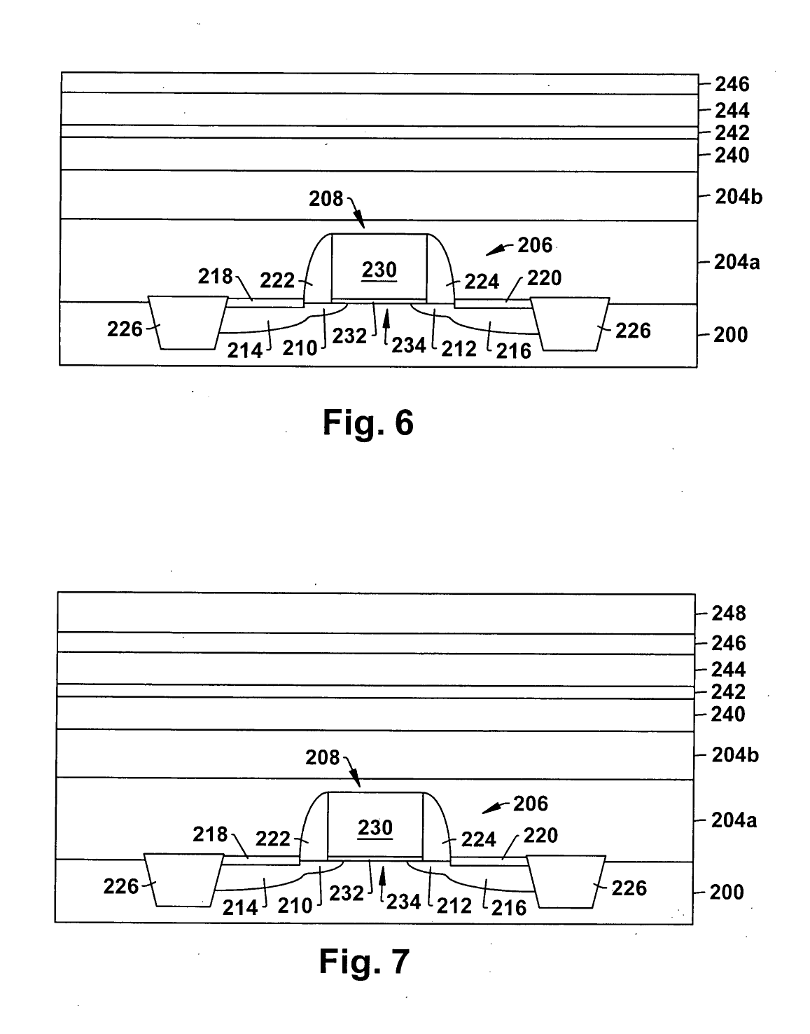

To mitigate this threshold voltage shifting (and thus the shortening of the life expectancy of the transistor 206), a third layer of dielectric material 246 is formed over the second layer of dielectric passivation material 244 at 108 (FIG. 6), and a fourth layer of dielectric passivation material 248 is formed over the third layer of dielectric material 246 at 110 (FIG. 7). The third layer of dielectric material 246 may comprise a nitride based material, for example, formed to a thickness of between about 100 Angstroms and about 600 Angstroms, for example. The fourth layer of dielectric passivation material 248 may comprise a polymer based material (e.g., poly-benzoxasole), for example, formed to a thickness of between about 10 kilo Angstroms and about 200 kilo Angstroms, for example. The fourth layer of dielectric passivation material 248 is at times referred to as PBO, and an anneal may be performed (e.g., in a nitrogen atmosphere) to cure the PBO. The third 246 and fourth 248 layers of dielectric materials can be patterned as needed to facilitate the application of external voltages, for example.

It will be appreciated that given the nature of the material(s) applied, layer 248 may be under tension, and that this tension serves to counteract at least some of the compression applied to the channel region 234 by layers 244 and 240. Accordingly, in addition to adding extra protection from external contaminants, shocks, vibrations, etc., layer 248 also serves to extend the life expectancy of transistor 206 by mitigating threshold voltage shifting (e.g., by counteracting compression that can exacerbate threshold voltage shifting). Similarly, it will also be appreciated that layer 248 can be treated (e.g., heated, cooled and/or applied in the presence of other materials) so that it is under compression. This may be desirable, for example, to counteract at least some of the tension from layers 244 and 240 when one or more of these layers 244 and 240 are under tension.

It will also be appreciated that instead of forming layer 248, an anneal can merely be performed to “relax” layers 244 and 240 and thereby mitigate the compression therein, and thus the amount of compression transferred to the channel region 234. Such an anneal can be performed, for example, in an atmosphere of nitrogen where the temperature is substantially linearly increased from about 150 degrees Celsius to about 320 degrees Celsius in about 84 minutes, is maintained at about 320 degrees Celsius for about 60 minutes and is decreased in a substantially linear fashion from about 320 degrees Celsius to about 150 degrees Celsius over the course of about 48 minutes, for example. In this example, the third layer of dielectric material 246 may be omitted since this layer 246 serves, at least in part, as a buffer between the second 244 and fourth 248 layers of dielectric passivation material. Additionally, this annealing process may correspond to the annealing process implemented when the PBO layer 248 is formed.

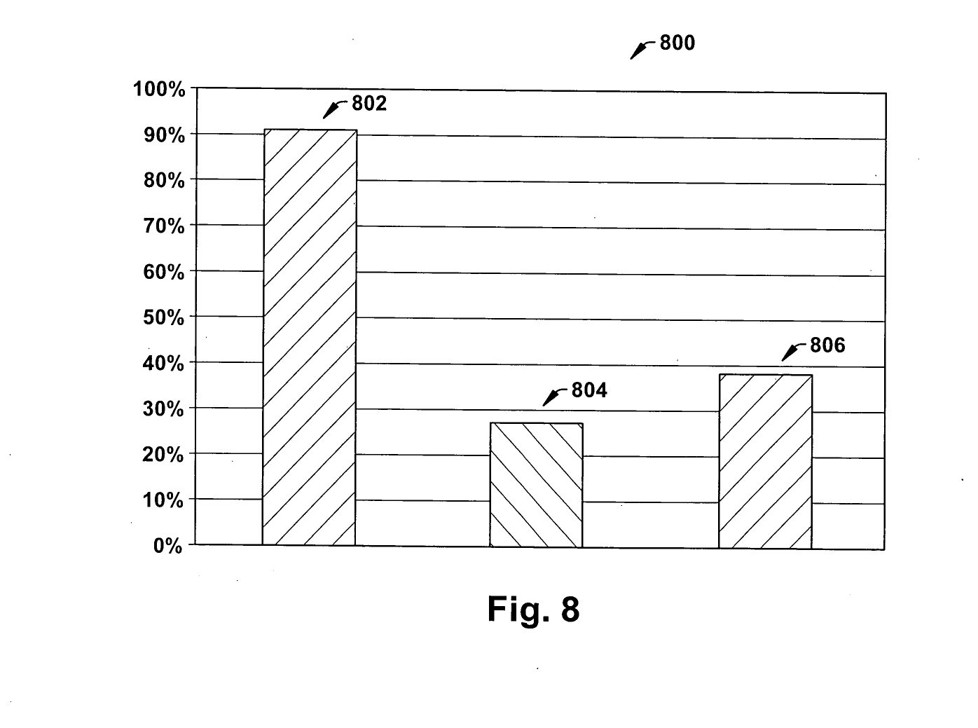

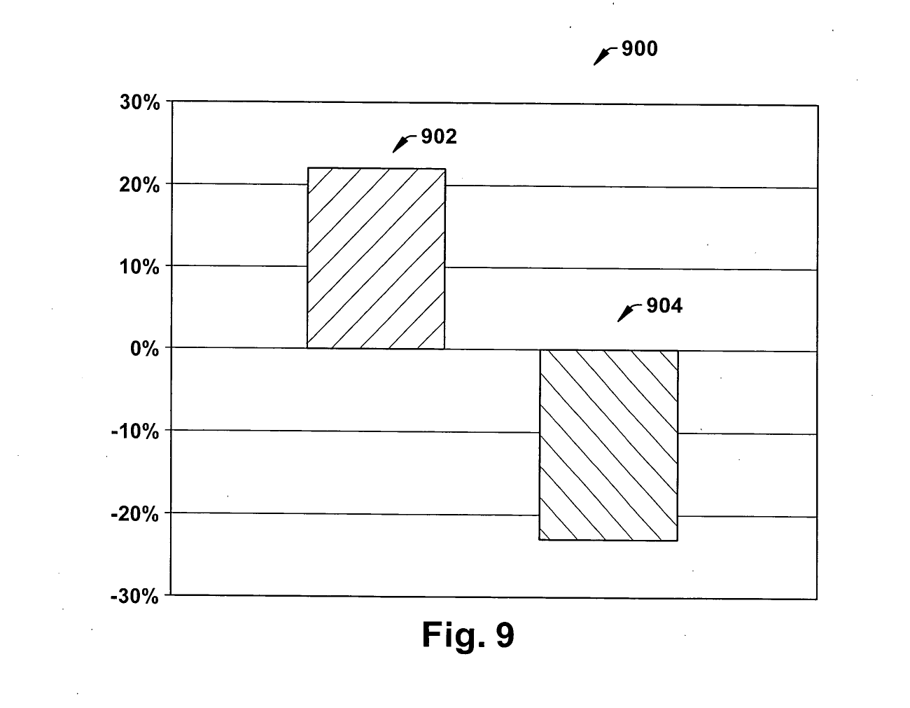

Turning to FIGS. 8 and 9, graphs 800 and 900 are shown which illustrate the mitigation of threshold voltage shifting when a PBO layer 248 and/or an anneal is implemented. With regard to FIG. 8, the percentage of threshold voltage shifting is illustrated for three conditions, namely 1) where neither the PBO layer 248 nor the anneal are implemented 802, 2) where the PBO layer 248 (and the third layer of dielectric material 246) and the associated anneal are implemented 804 and 3) where merely the anneal is implemented 806.

It can be seen from the first column 802 in FIG. 8, that where neither the PBO layer 248 nor the anneal are implemented, that the threshold voltage can shift by around 90 percent. For example, if the threshold voltage of the transistor 206 shifts by around 152 milli volts over 10 years when the compression inducing second layer of dielectric passivation material 244 is included, but merely shifts by around 80 milli volts over 10 years when the compression inducing second layer of dielectric passivation material 244 is not included, then this would equate to about a 90 percent shift (e.g., 72 milli volts divided by 80 milli volts, where the 72 milli volts is the difference in threshold voltage shifting with layer 244 (e.g., 152 milli volts) and without layer 244 (e.g., 80 milli volts)). It can be appreciated that such a shift in threshold voltage may increase yield loss by shortening the life expectancy of the transistor 206, for example. That is, the transistor may be designed/required to operate in a desired and/or predictable manner for a certain period of time (e.g., 10 years). However, the device may not operate as desired once the threshold voltage shifts a certain amount, such as to around 125 milli volts, for example. This shifting may happen within 6, rather than 10, years, for example, making the device unsuitable for its intended purpose. Accordingly, the device may have to be discarded because it is not in compliance with certain design specifications.

The second column 804 in FIG. 8 illustrates that threshold voltage shifting may be reduced to around 25 percent when the PBO layer 248 (and the third layer of dielectric material 246) and an associated anneal are implemented. For example, if the threshold voltage of the transistor 206 shifts by around 100 milli volts over 10 years when the PBO layer 248 (and the third layer of dielectric material 246) and an associated anneal are implemented over the compression inducing second layer of dielectric passivation material 244, but merely shifts by around 80 milli volts over 10 years when none of these layers are implemented, then this would equate to about a 25 percent shift (e.g., 20 milli volts divided by 80 milli volts, where the 20 milli volts is the difference in threshold voltage shifting with layers 248, 246 and 244 (e.g., 100 milli volts) and without any of these layers (e.g., 80 milli volts)). It can be appreciated that this can mitigate yield loss by extending the useable life of the transistor 206 to an acceptable duration.

Similarly, the third column 806 illustrates that threshold voltage shifting may be reduced to around 37 percent when merely an anneal is performed. For example, if the compression inducing second layer of dielectric passivation material 244 is merely subjected to an anneal (e.g., in a nitrogen atmosphere), and the threshold voltage of the transistor 206 resultantly shifts by around 110 milli volts over 10 years, but merely shifts by around 80 milli volts over 10 years when layer 244 and the anneal are not implemented, then this would equate to about a 37 percent shift (e.g., 30 milli volts divided by 80 milli volts, where the 30 milli volts is the difference in threshold voltage shifting with the anneal and layer 244 (e.g., 110 milli volts) and without layer 244 and the anneal (e.g., 80 milli volts)). It can be appreciated that this can likewise mitigate yield loss by allowing the transistor to operate in a predictable or otherwise desirable manner for an acceptable duration.

FIG. 9 illustrates threshold voltage shifting for a different technology, namely where the gate dielectric 232 comprises more nitrogen that the gate dielectric of transistor(s) utilized to generate the columns in FIG. 8. The first column 902 in FIG. 9 illustrates that, with this technology, the threshold voltage merely shifts by around 20 percent when the compression inducing second layer of dielectric material 244 is implemented. Column 904, on the other hand, illustrates that the threshold voltage shifting is negative with this technology when the PBO layer 248 (and the third layer of dielectric material 246) and the associated anneal are implemented over layer 244. That is, the threshold voltage actually shifts down (rather than up) in this technology when the PBO layer 248 and the associated anneal are implemented. It can thus be appreciated that, in addition to providing additional protection, implementing the PBO layer 248 and the associated anneal may actually extend the useful life of the transistor. For example, if the threshold voltage normally shifted beyond an acceptable range after 10 years, then (depending upon the technology involved) that time frame may be extended out to 15 years, for example.

It will be appreciated that the expected or useful life of different transistors can be determined by taking measurements of the transistors and making extrapolations as to how the transistors will perform. For example, respective threshold voltages can be measured for the transistors under normal operating conditions (e.g., applied bias voltages). The transistors can then be “stressed” by applying substantially higher voltages to their respective gates, while grounding their source and drain regions, for example, to accelerate the “aging” of the transistors. Threshold voltages of these “aged” transistors can then be obtained again under normal operating conditions (e.g., applied voltages) to see if there has been any threshold voltage shifting. Extrapolation can be performed to further reveal threshold voltage shifting.

It will be appreciated that, substrate and/or semiconductor substrate as used herein may comprise any type of semiconductor body (e.g., silicon, SiGe, SOI) such as a semiconductor wafer and/or one or more die on a wafer, as well as any other type of semiconductor and/or epitaxial layers associated therewith. Also, while reference is made throughout this document to exemplary structures in discussing aspects of methodologies described herein (e.g., those structures presented in FIGS. 2-7 while discussing the methodology set forth in FIG. 1), that those methodologies are not to be limited by the corresponding structures presented. Rather, the methodologies (and structures) are to be considered independent of one another and able to stand alone and be practiced without regard to any of the particular aspects depicted in the Figs. Additionally, layers described herein, can be formed in any suitable manner, such as with spin on, sputtering, growth and/or deposition techniques, etc.

Also, equivalent alterations and/or modifications may occur to those skilled in the art based upon a reading and/or understanding of the specification and annexed drawings. The disclosure herein includes all such modifications and alterations and is generally not intended to be limited thereby. In addition, while a particular feature or aspect may have been disclosed with respect to only one of several implementations, such feature or aspect may be combined with one or more other features and/or aspects of other implementations as may be desired. Furthermore, to the extent that the terms “includes”, “having”, “has”, “with”, and/or variants thereof are used herein, such terms are intended to be inclusive in meaning—like “comprising.” Also, “exemplary” is merely meant to mean an example, rather than the best. It is also to be appreciated that features, layers and/or elements depicted herein are illustrated with particular dimensions and/or orientations relative to one another for purposes of simplicity and ease of understanding, and that the actual dimensions and/or orientations may differ substantially from that illustrated herein

What is claimed is:

1. A method for implementing passivation layers in a semiconductor fabrication process while mitigating threshold voltage shifting that may result there-from, comprising:
forming one or more back end layers of conductive, semi-conductive and/or non-conductive/dielectric layers over a semiconductor device formed in/on a semiconductor substrate;
forming a first layer of dielectric passivation material over the back end layers;
forming a first layer of conductive material over the first layer of dielectric passivation material;
forming a second layer of dielectric passivation material over the first layer of conductive material; and
forming a fourth layer of dielectric passivation material over the second layer of dielectric passivation material.

2. The method of claim 1, comprising:
performing an anneal in forming the fourth layer of dielectric passivation material.

3. The method of claim 2, at least one of:
the fourth layer of dielectric passivation material being under tension and at least one of the first layer of dielectric passivation material and the second layer of dielectric passivation material being under compression, and
the fourth layer of dielectric passivation material being under compression and at least one of the first layer of dielectric passivation material and the second layer of dielectric passivation material being under tension.

4. The method of claim 3, at least one of:
the first layer of dielectric passivation material comprising silicon nitride and/or silicon oxide nitride and/or silicon oxide based materials, and
the first layer of dielectric passivation material formed to a thickness of between about 4 kilo Angstroms and about 24 kilo Angstroms.

5. The method of claim 4, the second layer of dielectric passivation material comprising silicon nitride and/or silicon oxide nitride and/or silicon oxide based materials.

6. The method of claim 5, the second layer of dielectric passivation material formed to a thickness of between about 4 kilo Angstroms and about 24 kilo Angstroms.

7. The method of claim 6, the fourth layer of dielectric passivation material comprising a polymer based material.

8. The method of claim 7, the fourth layer of dielectric passivation material formed to a thickness of between about 50 kilo Angstroms and about 500 kilo Angstroms.

9. The method of claim 8, the fourth layer of dielectric passivation material comprising poly-benzoxasole.

10. The method of claim 9, comprising:
forming a third layer of dielectric material over the second layer of dielectric passivation material; and
forming the fourth layer of dielectric passivation material over the third layer of dielectric material.

11. The method of claim 10, the third layer of dielectric material comprising a nitride based material.

12. The method of claim 11, the third layer of dielectric material formed to a thickness of between about 100 Angstroms and about 600 Angstroms.

13. The method of claim 12, first layer of conductive material comprising a metal formed to a thickness of between about 4 kilo Angstroms and about 15 kilo Angstroms.

14. A method for implementing passivation layers in a semiconductor fabrication process while mitigating threshold voltage shifting that may result there-from, comprising:
forming one or more back end layers of conductive, semi-conductive and/or non-conductive/dielectric layers over a semiconductor device formed in/on a semiconductor substrate;
forming a first layer of dielectric passivation material over the back end layers;
forming a first layer of conductive material over the first layer of dielectric passivation material;
forming a second layer of dielectric passivation material over the first layer of conductive material; and
performing an anneal to relax tension or compression in the first and second layers of dielectric passivation material.

15. The method of claim 14, performing the anneal comprising:
increasing the temperature from about 150 Degrees Celsius to about 320 degrees Celsius in about 84 minutes;
maintaining the temperature at about 320 degrees Celsius for about 60 minutes; and
decreasing the temperature from about 320 degrees Celsius to about 150 degrees Celsius in about 48 minutes.

16. The method of claim 15, the temperature increased and decreased in a substantially linear manner.

17. The method of claim 16,
the first layer of dielectric passivation material comprising silicon nitride and/or silicon oxide nitride and/or silicon oxide based materials formed to a thickness of between about 4 kilo Angstroms and about 24 kilo Angstroms, and
the second layer of dielectric passivation material comprising silicon nitride and/or silicon oxide nitride and/or silicon oxide based materials formed to a thickness of between about 4 kilo Angstroms and about 24 kilo Angstroms

18. A semiconductor passivation arrangement, comprising:
one or more back end layers of conductive, semi-conductive and/or non-conductive/dielectric layers formed over a semiconductor device formed in/on a semiconductor substrate;
a first layer of dielectric passivation material formed over the back end layers;
a first layer of conductive material formed over the first layer of dielectric passivation material;
a second layer of dielectric passivation material formed over the first layer of conductive material; and
a fourth layer of dielectric passivation material formed over the second layer of dielectric material.

19. The arrangement of claim 18,
the first layer of dielectric passivation material comprising silicon nitride and/or silicon oxide nitride and/or silicon oxide based materials formed to a thickness of between about 4 kilo Angstroms and about 24 kilo Angstroms,
the second layer of dielectric passivation material comprising silicon nitride and/or silicon oxide nitride and/or silicon oxide based materials formed to a thickness of between about 4 kilo Angstroms and about 24 kilo Angstroms, and the fourth layer of dielectric passivation material comprising a polymer based material formed to a thickness of between about 10 kilo Angstroms and about 200 kilo Angstroms.

20. The arrangement of claim 19, comprising:
a third layer of dielectric material formed over the second layer of dielectric passivation material, the fourth layer of dielectric passivation material formed over the third layer of dielectric material,
the third layer of dielectric material comprising a nitride based material formed to a thickness of between about 100 Angstroms and about 600 Angstroms.
